(19) United States
(12) Patent Application Publication
(10) Pub. No.: US 2016/0005679 A1
(43) Pub. Date: Jan. 7, 2016

(54) EXPOSED DIE QUAD FLAT NO-LEADS (QFN) PACKAGE

(71) Applicant: NXP B.V., Eindhoven (NL)

(72) Inventors: Emil Casey Israel, Nijmegen (NL); Leonardus Antonius Elisabeth van Gemert, Nijmegen (NL); Roelf Anco Jacob Groenhuis, Nijmegen (NL)

(21) Appl. No.: 14/322,419

(22) Filed: Jul. 2, 2014

(51) Int. Cl. H01L 23/495; H01L 23/00; H01L 21/304; H01L 21/56; H01L 21/78; H01L 23/31; H01L 21/683

(52) U.S. Cl. CPC H01L 23/49562; H01L 23/3107; H01L 24/49; H01L 21/6836; H01L 24/96; H01L 24/97; H01L 21/561; H01L 21/78; H01L 24/85; H01L 21/304; H01L 2924/01028; H01L 2924/01079; H01L 2924/01029; H01L 2924/01046; H01L 2924/0105; H01L 2924/01047; H01L 2924/01022; H01L 2924/01024; H01L 2924/014; H01L 2924/0132; H01L 2924/15311; H01L 2924/13091; H01L 2924/14; H01L 2224/48177; H01L 2221/68327

(57) ABSTRACT

Consistent with an example embodiment, there is a method for packaging an integrated circuit (IC) device. The method comprises attaching a lead frame to the carrier tape; the lead frame has an array of device positions on the carrier tape and pad landings surround the device positions for making electrical connections to the plurality of active device die. A plurality of active device die are mounted on the carrier tape within the array of device positions; each said active device die has bond pads, each of said active device die has been subjected to back-grinding to a prescribed thickness and has a solderable conductive surface on its underside. On the bond pads, the plurality of active devices are wire bonded to the pad landings on the lead frame. The lead frame and wire bonded active devices are encapsulated, leaving the solderable die backside and lead frame backside exposed.

### FIELD

This disclosure relates to integrated circuit (IC) packaging. More particularly, this disclosure relates to QFN packaging with a reduced vertical profile and an exposed underside surface providing enhanced thermal performance.

### BACKGROUND

The electronics industry continues to rely upon advances in semiconductor technologies to realize higher-function devices in more compact areas. For many applications realizing higher-functioning devices requires integrating a large number of electronic devices into a single silicon wafer. As the number of devices per given area of the silicon wafer increases, the manufacturing process becomes more difficult.

Many varieties of semiconductor devices have been manufactured having various applications in numerous disciplines. Such silicon-based semiconductor devices often include metal-oxide-semiconductor field-effect transistors (MOSFET), such as p-channel MOS (PMOS), n-channel MOS (NMOS) and complementary MOS (CMOS) transistors, bipolar transistors, BiCMOS transistors. Such MOSFET devices include an insulating material between a conductive gate and silicon-like substrate; therefore, these devices are generally referred to as IGFETs (insulated-gate FET).

Having manufactured a number of electronic devices on a wafer substrate, a particular challenge is to package these devices for their given purpose. As the complexity of portable systems increases, there is a commensurate need to reduce the size of the individual components which make up the system; the system often is laid out on a printed circuit substrate. One way to reduce the size of individual components is through techniques that reduce the size of packages which contain these devices. A package, often used, is the QFN (quad flat no-leads) package to reduce the vertical profile of the devices attached to the system printed circuit substrate. However, even with this package, there is a need for a QFN package which even further reduces the amount of printed circuit substrate space consumed.

### SUMMARY

The present disclosure addresses the challenge of making a QFN packaged semiconductor having a lower vertical profile with enhanced thermal performance. This is obtained by having the backside of the die exposed in the package. The die backside has a solderable coating so that minimal thermal resistance is achieved between the die junction and the printed circuit board to which the packaged device is attached. Furthermore, the exposed die backside provides for a high-integrity electrical connection between the device die and printed circuit board (PCB) to which it is soldered.

In an example embodiment, there is method for packaging an integrated circuit (IC) device. The method comprises, attaching a lead frame to the carrier tape; the lead frame has an array of device positions on the carrier tape and pad landings surround the device positions for making electrical connections to the plurality of active device die. A plurality of active device die within the array of device positions are mounted, each said active die has bond pads; each of said active device die has a solderable conductive surface on its underside and has been subjected to back-grinding to a prescribed thickness. With conductive bonds, the bond pads of the plurality of active devices are connected to the pad landings on the lead frame. The lead frame and conductively bonded active devices are encapsulated in a molding compound. An additional feature of this embodiment, is that wire bonding or ribbon bonding may be selected for the conductive bonding.

In another example embodiment, there is a method for packaging an integrated circuit (IC) device from a semiconductor wafer substrate, the wafer substrate having a top-side surface with a plurality active device die defined thereon, and an under-side surface. The method comprises back-grinding the under-side surface of the wafer substrate to a prescribed thickness; applying a solderable conductive surface to the under-side surface of the wafer substrate; separating out the plurality active device die from the semiconductor wafer substrate, each of the active device die having bond pads, the bond pads providing electrical connection to circuit elements in the active device die; and attaching the active device to a package assembly.

In an example embodiment, there is a MOSFET integrated circuit (IC) device assembled in a QFN package, The IC comprises an active device die has a solderable conductive surface on its under-side and has been subjected to back-grinding to a prescribed thickness and a top side surface, the active device die has a drain, source, and gate. The source is connectable via the underside surface. A lead frame assembly surrounds the active device die, the lead frame assembly has pad landings on top-side surfaces and corresponding under-side surfaces opposite the top-side surface, the source drain, and gate of the active device die are connected to respective pad landings on the top-side surface of the lead frame assembly. An encapsulant envelopes the active device die and lead frame assembly; the solderable conductive surface and under-side surfaces of the lead frame assembly are exposed and coplanar with one another. An additional feature is that the source, drain, and gate are connected to respective pad landings with either wire bonds or ribbon bonds.

The above summaries of the present invention are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIGS. 1 is a flow diagram of an example assembly process in accordance with the present disclosure;

FIGS. 2A-2E are side views of an exposed die QFN package assembled in accordance with the present disclosure; and

FIG. 3 is an example embodiment of an exposed-die QFN package whose encapsulated device has a profile defined to enhance mechanical anchoring to the molding compound;

FIGS. 4A-4E is an example embodiment of an exposed-die BGA package assembled in accordance with the present disclosure; and

FIG. 5 is an example embodiment of a singulated exposed-die BGA package assembled in accordance with the present disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present disclosure has been found useful in reducing the vertical profile in a FET device assembled in a QFN package. Additionally, the FET in the “On” state, the drain/source resistance (i.e., R_{Dson}) is reduced. It is desirable that the R_{DSon} be as low as possible so as to reduce the electrical power loss inside the package. These devices may be expected to dissipate about 100 mW to about 5 W, or more. The degree of grinding and the back side metallization affect the R_{DSon} and thermal resistance of the finished device product. In an example process the wafers are ground down to about 200 μm. To further reduce the R_{DSon} and thermal resistance, in another example process, the wafer thickness may be reduced down to 50 μm, after this process the back side metallization is applied. This metallization is in the order of a few micro-meters thick. One, or more metallization deposition techniques may be applied or even a combination of them (e.g., initial sputter layer which is increased in thickness by a plating process). Other variations of the leadless packages placed on a temporary carrier may include, but are not necessarily limited to,advanced quad flat no lead (aQFN), leadless land grid array (LLAGA), thermal leadless array (TLA), electroforming type land grid array (EFLGA), transcription lead of electro forming method (TLEM), high density lead frame array (HLA), and embedded wafer ball grid array (eWLB).

Besides reducing the R_{Dson}, in some devices, the underside metallization may be desirable in devices having critical signaling requirements in that a stable ground or voltage reference is necessary (e.g., the avoidance of ground bounce). The underside metallization provides for a uniform electrical potential across the back surface of the device die. This potential can be defined by a PCB ground or voltage plane. Further, the present disclosure obviates the need to attach a separate heat sink to the device or QFN package in that the underside of the device die is in direct contact with the with the PCB; the PCB provides a large area in which heat may be dissipated.

In this disclosure the die backside is coated on wafer level with a solderable finish (i.e., NiAu, Cu, NiAg, etc.). Any solderable finish can be used, as long as the solderabilty is not deteriorated by the processing conditions and allows storage for a sufficient period between package assembly and customer use. A reliably solderable finish is integral to a successful packaging process.

With the trend toward more environmentally friendly materials, the use of lead-based (Pb) solder being phased out, Pb-free alternatives have been brought to the fore for board-level soldering of packages to PCB. In contrast, no good replacement for tin-lead (SnPb) solder has yet been identified for die-attach material in power packaging. Power packages made according to this disclosure would satisfy Pb-free legislation since SnPb solder is not used in the package construction.

A Pb-free alloy, for example, is tin-silver-copper (SnAgCu, also known as SAC). The SAC alloy is the prevailing alloy system used to replace SnPb for board-level soldering of packages to PCB because it is near eutectic, with adequate thermal fatigue properties, strength, and wettability. Of particular note, SAC solder has twice the thermal conductivity of SnPb solder, so that in this disclosure, the thermal resistance from die to PCB is reduced since SnPb solder is not used in the package construction.

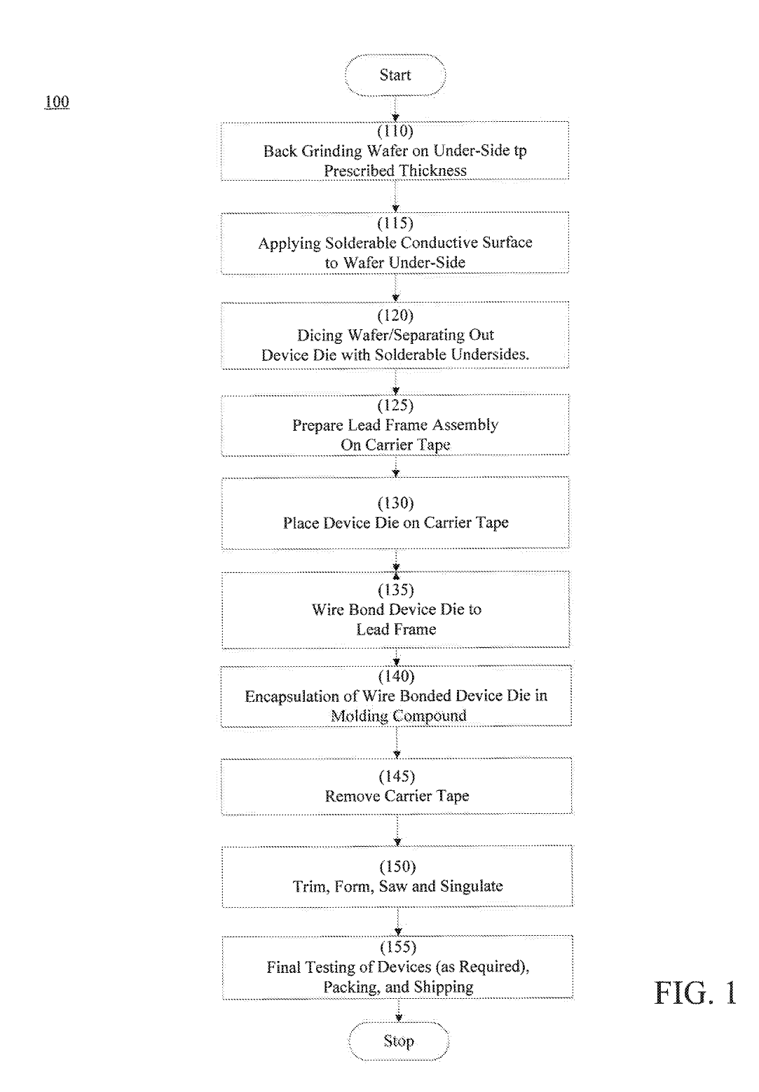

Making reference to FIG. 1, in an example process 100 according to the disclosure, a wafer substrate on its under-side undergoes back-grinding to a prescribed thickness 110. After back-grinding, a solderable conductive surface is applied to the wafer's under-side 115. The solderable conductive surface may be applied with a variety of techniques, which may include, but are not limited to, sputtering, evaporation, chemical vapor deposition, electro-plating, or a combination thereof. Solderable conductive surfaces may include NiAu, Cu, NiAg, or other suitable alloys. Of particular importance, the solderable conductive surfaces should be compatible with Pb-free solders, such as SAC.

It is worth noting that before the solderable coating is applied to the underside surface of the back-ground wafer, as a first layer, an adhesion layer of titanium (Ti), chromium (Cr), or others is often applied. The subsequent metals may be in the form of metal stacks. For example, a complete metal stack may include TiNiAg, CrNiAg, TiNiAu, CrNiAu, etc. Often the solderable coating will be expressed in terms of the last two or three layers or surfaces. Having coated the wafer under-side, the wafer is diced and device die, having solderable under-sides, are separated out 20. Dicing of the wafer may be accomplished with sawing, cleaving, laser ablation or other suitable method. As determined by the device die type, a lead frame assembly is prepared and placed on carrier tape 125.

In an example embodiment, a lead frame vendor may supply the lead frame array with backside tape already attached. Or alternatively the user may apply lead frames to a temporary carrier strip. For example, as a carrier tape, REVALPHA®, a two-sided adhesive tape may be used. REVALPHA is the trademark of thermal release sheet material for electronic component processing manufactured by Nitto Denko Corporation, Osaka, Japan. At room temperature, the tape adheres securely. With application of heat the tape loses its adhesion. Depending upon a particular process the tape may be selected to release at 90° C., 120° C., 150° C. or 170° C. Having prepared the lead frames, the device die are placed on the carrier tape, solder-side down 130 in an area surrounded by the lead frame contacts. The device die are then wire bonded or ribbon bonded from pad landings in the active device area to corresponding lead frame contacts 135. The wire bonded device and lead frame assembly is encapsulated into a molding compound 140. Carrier tape is removed 140. The assembled array of encapsulated device die is then sawed apart into individual assembled device die whose lead frame contacts are exposed, as well, as the solderable under-side 150. As required by the end-user, the devices may undergo a final testing, be prepared for packing, and shipping 155.

In another example embodiment, the use of wire bonds may not be appropriate, especially were minimizing interconnect inductance and/or resistance is critical. Ribbon bonding may often be used. For a given application, a wire bond may have a given diameter of about 25.4 μm (0.001 in) and a ribbon bond may have a cross-section of about 25.4 μm×76.2 μm (0.001 in×0.003 in). Interconnect inductance can cause impedance mismatches, ringing, distortion pulses. For high speed circuits, excess inductance results in reduced bandwidth. Because of this need for reduced inductance, ribbon bonding may often specified instead of wire bonding. This is especially true for wide band components where parameters such as group delay must be controlled over a very wide bandwidth. Ribbon bonds may be preferred because a typical ribbon bond has two to three times less inductance than that of a wire bond. The increased cross-sectional area serves to lower the resistance of typical ribbon bonds compared to typical wire bonds, which in turn lowers R_{DSon} in relevant electrical pathways. More detailed information may be found in “Quick Reference Guide: Ribbon Bond vs. Wire Bond.” NATEL Engineering Co., Inc., Chatsworth, Calif., USA, pp.4.

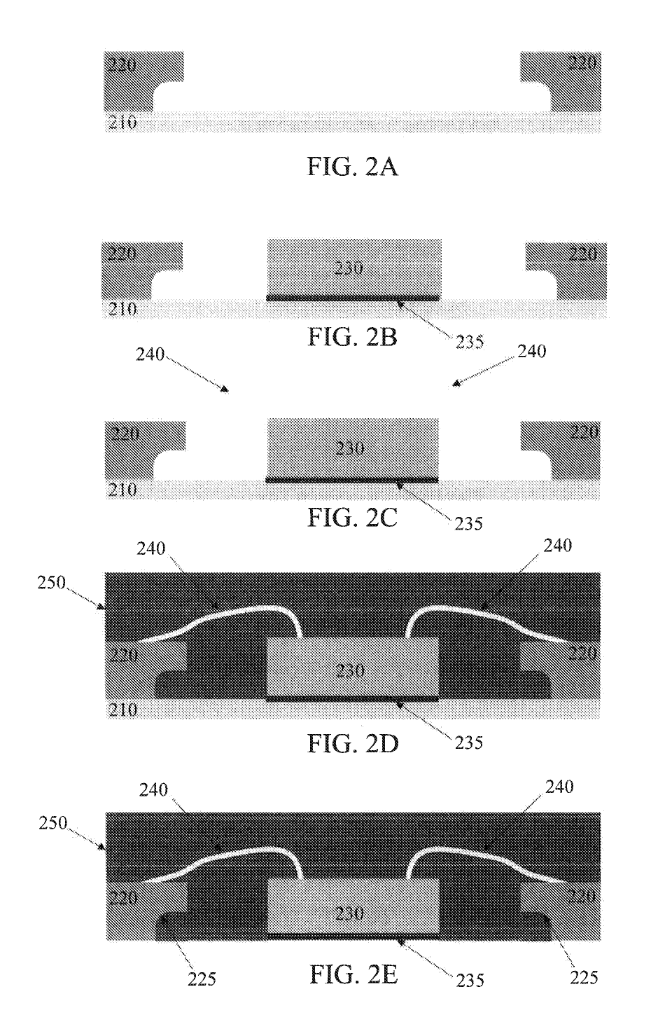

In an example embodiment, as depicted in FIGS. 2A-2E, a series of side views illustrate the assembly of a device die according to the disclosure. FIG. 2A shows lead frame contacts 220 mounted onto carrier tape 210. The carrier tape 210 may be held by a carrier ring apparatus, not illustrated. A device die 230 upon its under-side to which a solderable conductive surface 235 has been applied, is mounted onto the carrier tape 210. (See FIG. 2B). Bond wires 240 electrically connect active areas of the device die to the lead frame contacts 220. The mounted and wire bonded device die are encapsulated in a molding compound 250. After molding, the carrier tape 210 is removed (See FIG. 2E). Note that the molding compound 250 has enhanced mechanical anchoring at the overhangs 225 of the lead frame 220. In example processes, the lead frame may be 50 mm×200 mm or 80 mm×300 mm, though other sizes may be available owing to the particular assembly equipment used.

The number of fabricated devices can range from a few hundred to even several thousand pieces on a strip. In an example embodiment, assembly is often done on an array (i.e., matrix) which is dependent upon package size. Pin counts may vary from 2 to about 100. For a two-lead package the package length and width may be 0.5 mm×0.3 mm; a three-lead package length and width may be 0.5 mm×1 mm; an 88 lead package may have a length and width of about 10 mm×10 mm.

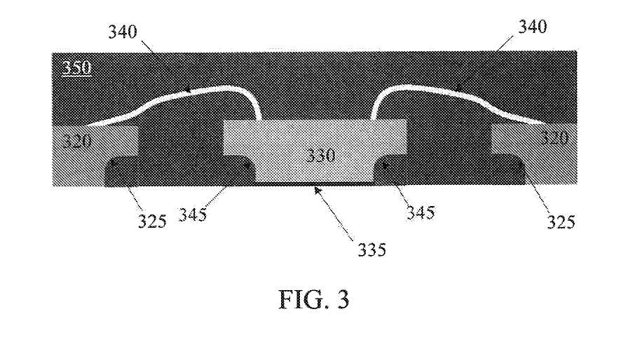

Making reference to FIG. 3, in an example embodiment, an assembled device die 330 having a solderable conductive surface 335 has been wire bonded 340 to the lead frame 320. The device die 330 has been prepared with over hangs 345 to augment the mechanical anchoring of the molding compound 350 afforded by overhangs 325 of the lead frame 320.

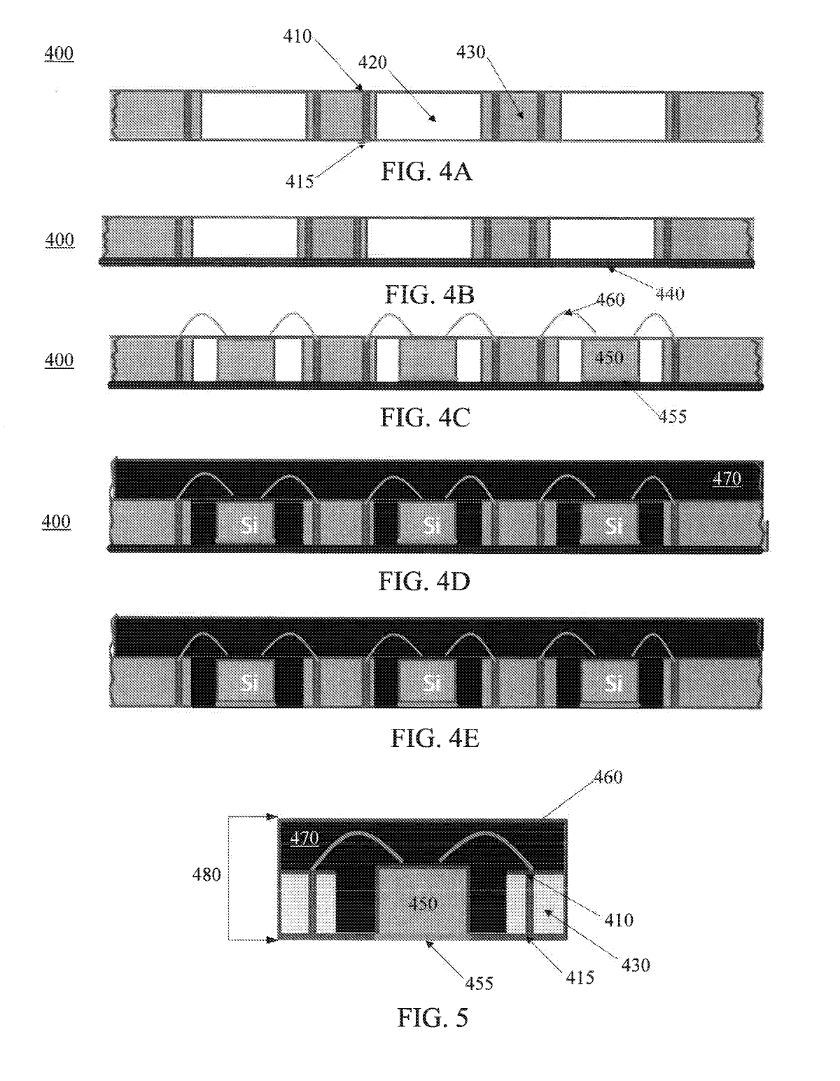

Refer to FIGS. 4A-4F. In an example embodiment, a BGA package array 400 may be assembled in accordance with the present disclosure. The array 400 has cavities 420 having an open underside and the array is placed onto a carrier tape 440. A silicon device die 450 is placed in the cavity 420. Vertical conductive traces 410 in the insulating package substrate material 430, provide a connection from bond pads on the device via bond wires 460 to contacts 415 on the underside of the BGA package 400. Molding compound 470 encapsulates the silicon device die 450 and the bond wires 460. The finished package device 480 is shown in FIG. 5.

Various exemplary embodiments are described in reference to specific illustrative examples. The illustrative examples are selected to assist a person of ordinary skill in the art to form a clear understanding of, and to practice the various embodiments. However, the scope of systems, structures and devices that may be constructed to have one or more of the embodiments, and the scope of methods that may be implemented according to one or more of the embodiments, are in no way confined to the specific illustrative examples that have been presented. On the contrary, as will be readily recognized by persons of ordinary skill in the relevant arts based on this description, many other configurations, arrangements, and methods according to the various embodiments may be implemented.

To the extent positional designations such as top, bottom, upper, lower have been used in describing this disclosure, it will be appreciated that those designations are given with reference to the corresponding drawings, and that if the orientation of the device changes during manufacturing or operation, other positional relationships may apply instead. As described above, those positional relationships are described for clarity, not limitation.

The present disclosure has been described with respect to particular embodiments and with reference to certain drawings, but the invention is not limited thereto, but rather, is set forth only by the claims. The drawings described are only schematic and are non-limiting. In the drawings, for illustrative purposes, the size of various elements may be exaggerated and not drawn to a particular scale. It is intended that this disclosure encompasses inconsequential variations in the relevant tolerances and properties of components and modes of operation thereof. Imperfect practice of the invention is intended to be covered.

Where the term “comprising” is used in the present description and claims, it does not exclude other elements or steps. Where an indefinite or definite article is used when referring to a singular noun, e.g. “a” “an” or “the”, this includes a plural of that noun unless something otherwise is specifically stated. Hence, the term “comprising” should not be interpreted as being restricted to the items listed thereafter; it does not exclude other elements or steps, and so the scope of the expression “a device comprising items A and B” should not be limited to devices consisting only of components A and B. This expression signifies that, with respect to the present disclosure, the only relevant components of the device are A and B.

Numerous other embodiments of the disclosure will be apparent to persons skilled in the art without departing from the spirit and scope of the disclosure as defined in the appended claims.

1-3. (canceled)

4. The method as recited in claim 8, wherein the solderable conductive surface includes alloys of: NiAu, Ni, Cu, Au, NiPdAu, AuSn, NiSn, CuSn, Ag, AgSn or combinations thereof.

5. The method as recited in claim 4, wherein the solderable conductive surface further includes an adhesion layer of Ti or Cr as a first layer on the under-side.

6-7. (canceled)

8. A method for packaging an integrated circuit (IC) device from a semiconductor wafer substrate, the wafer substrate having a top-side surface with a plurality active device die defined thereon, and an under-side surface, the method comprising:
back-grinding the under-side surface of the wafer substrate to a prescribed thickness;
applying a solderable conductive surface to the under-side surface of the wafer substrate;
separating out the plurality active device die from the semiconductor wafer substrate, each of the active device die having bond pads, the bond pads providing electrical connection to circuit elements in the active device die; and
attaching the active device to a package assembly.

9. The method as recited in claim 8, further comprising,
attaching the package assembly to a carrier tape, the package assembly having an array of device positions on the carrier tape and pad landings surrounding the device positions for making electrical connections to the plurality of active device die;
wherein solderable conductive under-side surfaces of the plurality of the active device die have been mounted onto the carrier tape within the array of the device positions; and
conductively bonding the plurality of active device to the pad landings on the lead frame; and
encapsulating the lead frame and the conductively bonded active devices;
wherein conductive bonding includes wire bonding, ribbon bonding, or a combination thereof.

10. The method as recited in claim 9, wherein the prescribed wafer thickness after back-grinding is less than about 50 μm.

11. The method as recited in claim 9, wherein the prescribed wafer thickness after back-grinding is in the range of about 50 μm to about 200 μm.

12. The method as recited in claim 9, wherein the package assembly is selected from one of the following package types: QFN, SMD, BGA, aQFN, LLGA, TLA, EFLGA, TLEM, HLA, or eWLB.

13. The method as recited in claim 12, wherein the carrier tape is further supported by a temporary carrier strip.

14. A metal oxide silicon field effect transistor (MOSFET) integrated circuit (IC) device assembled in a QFN package, the IC comprising:
an active device die having a Pb-free solderable conductive surface on its under-side and having been subjected to back-grinding to a prescribed thickness and a top side surface, the active device die having a drain, source, and gate;
wherein the drain is connectable via the underside surface;
a lead frame assembly surrounding the active device die, the lead frame assembly having pad landings on top-side surfaces and corresponding under-side surfaces opposite the top-side surface, the source and gate of the active device die connected to respective pad landings on the top-side surface of the lead frame assembly;
an encapsulant enveloping the active device die and lead frame assembly; and
wherein the Pb-free solderable conductive surface and under-side surfaces of the lead frame assembly are exposed and coplanar with one another.

15. The MOSFET IC as recited in claim 14, wherein the source and gate are connected to respective pad landings with either wire bonds or ribbon bonds.
